(19) United States
(12) Patent Application Publication
(10) Pub. No.: US 2026/0110092 A1
(43) Pub. Date: Apr. 23, 2026

(54) SUBSTRATE PROCESSING METHOD

(71) Applicant: Tokyo Electron Limited, Tokyo (JP)

(72) Inventors: Nobuo MATSUKI, Yamanashi (JP); Daisuke OBA, Albany, NY (US); Yoshinori MORISADA, Yamanashi (JP)

(21) Appl. No.: 19/423,169

(22) Filed: Dec. 17, 2025

Related U.S. Application Data
(63) Continuation of application No. PCT/JP2024/022865, filed on Jun. 24, 2024.

(30) Foreign Application Priority Data
Jul. 4, 2023 (JP) 2023-110189

(51) Int. Cl. C23C 16/48; C23C 16/448; H10P 50/00; H10P 50/28

(52) U.S. Cl. CPC C23C 16/48; C23C 16/448; H10P 50/283; H10P 50/73

(57) ABSTRACT

A substrate processing method is provided and includes forming a laminated structure film over a substrate, the laminated structure film including a metal-containing layer and a halogen-containing layer that are laminated; irradiating the laminated structure film with extreme ultraviolet light in a predetermined pattern to form, in the laminated structure film, an exposed portion irradiated with the extreme ultraviolet light and an unexposed portion not irradiated with the extreme ultraviolet light; and selectively removing the exposed portion of the laminated structure film.

### CROSS-REFERENCE TO RELATED APPLICATIONS

This application is a continuation application of International Application No. PCT/JP2024/022865, filed on Jun. 24, 2024, and designated the U.S., which is based upon and claims priority to Japanese Patent Application No. 2023-110189, filed on Jul. 4, 2023, the entire contents of which are incorporated herein by reference.

### BACKGROUND

### 1. Field of the Invention

The present disclosure relates to a substrate processing method.

### 2. Description of the Related Art

Japanese Laid-Open Patent Application Publication No. 2023-12048 discloses a pattern forming method including: forming a photosensitive hard mask formed of a transition metal oxide film over a surface of a substrate; exposing the photosensitive hard mask to extreme ultraviolet (EUV) light in a desired pattern; causing a state change to occur in the exposed region by heat during the exposure; and selectively removing a region in which the state change occurs or a region in which the state change does not occur.

### SUMMARY

In one aspect, a substrate processing method includes: forming a laminated structure film over a substrate, the laminated structure film including a metal-containing layer and a halogen-containing layer that are laminated; irradiating the laminated structure film with extreme ultraviolet light in a predetermined pattern to form, in the laminated structure film, an exposed portion irradiated with the extreme ultraviolet light and an unexposed portion not irradiated with the extreme ultraviolet light; and selectively removing the exposed portion of the laminated structure film.

### BRIEF DESCRIPTION OF THE DRAWINGS

FIG. 1 is a schematic cross-sectional diagram illustrating an example of a substrate processing apparatus according to the present embodiment.

FIG. 2 is a flowchart illustrating an example of a substrate processing method according to the present embodiment.

FIG. 3A is an example of a schematic cross-sectional diagram of a substrate including a resist film having a pattern of openings formed by the substrate processing method according to the present embodiment.

FIG. 3B is an example of a schematic cross-sectional diagram of the substrate including the resist film having the pattern of the openings formed by the substrate processing method according to the present embodiment.

FIG. 3C is an example of a schematic cross-sectional diagram of the substrate including the resist film having the pattern of the openings formed by the substrate processing method according to the present embodiment.

FIG. 4 is a diagram schematically illustrating a structure of the resist film having a laminated structure formed by the substrate processing apparatus according to the present embodiment.

FIG. 5 is a diagram schematically illustrating a structure, in each step, of the resist film of an exposed portion.

FIG. 6 is a diagram schematically illustrating a structure, in each step, of the resist film of an unexposed portion.

### DETAILED DESCRIPTION OF THE DISCLOSURE

In one aspect, the present disclosure provides a substrate processing method for forming a resist film that is a thin film and in which an exposed portion can be selectively removed.

Hereinafter, embodiments of the present disclosure will be described with reference to the drawings. In the drawings, the same components are denoted by the same reference signs, and duplicate description thereof may be omitted.

### Substrate Processing Apparatus

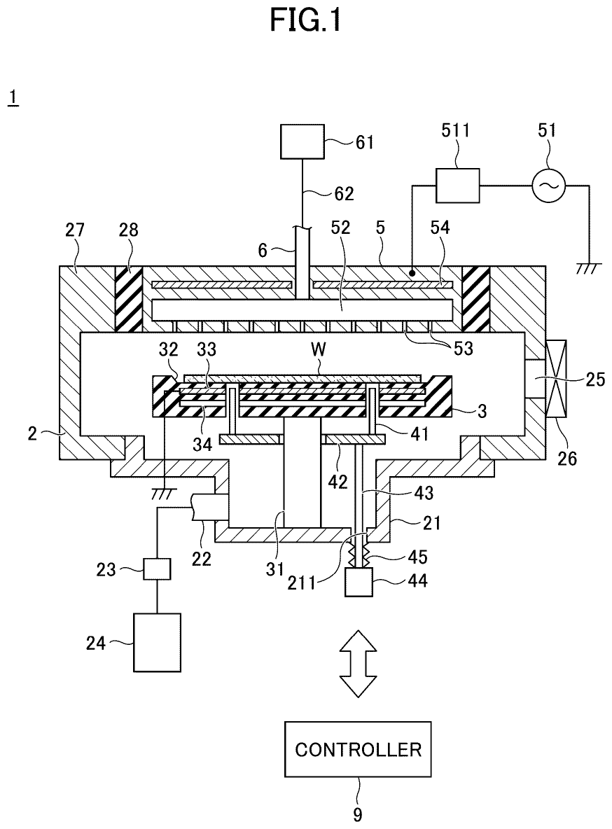

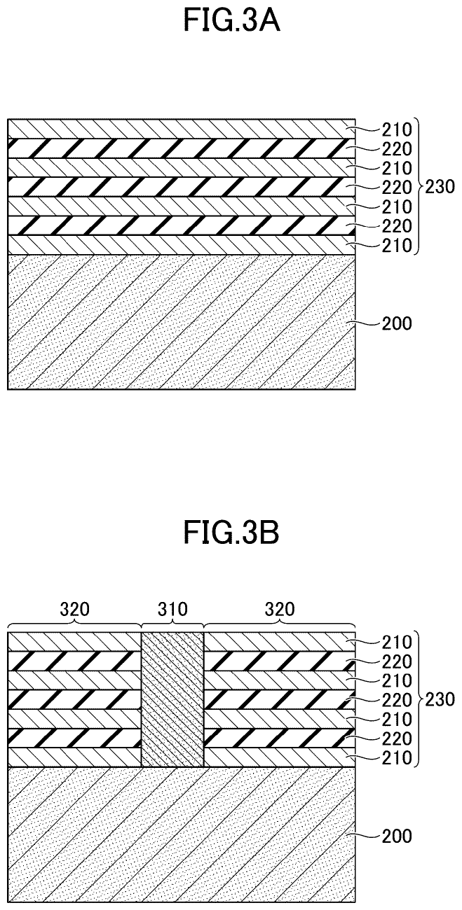

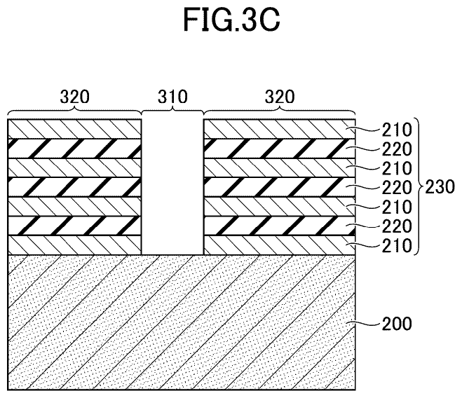

An example of a substrate processing apparatus 1 according to the present embodiment will be described with reference to FIG. 1. FIG. 1 is a schematic cross-sectional diagram illustrating an example of the substrate processing apparatus 1 according to the present embodiment. The substrate processing apparatus 1 is a film forming apparatus configured to form, over a substrate W (e.g., a semiconductor wafer), a resist film 230 having a laminated structure (laminated structure film) (see FIG. 3A described below) through chemical vapor deposition (CVD) using a plasma.

The substrate processing apparatus 1 includes a substantially cylindrical airtight processing chamber 2. A gas exhaust chamber 21 is provided at a center portion of the bottom wall of the processing chamber 2.

The gas exhaust chamber 21 has, for example, a substantially cylindrical shape that projects downward. A gas exhaust flow path 22 is connected to the gas exhaust chamber 21, for example, at a side surface of the gas exhaust chamber 21.

A gas exhauster 24 is connected to the gas exhaust flow path 22 via a pressure adjuster 23. The pressure adjuster 23 includes, for example, a pressure adjusting valve, such as a butterfly valve or the like. The gas exhaust flow path 22 is configured to reduce the internal pressure of the processing chamber 2 by the gas exhauster 24. A transfer port 25 is provided in a side surface of the processing chamber 2. The transfer port 25 is configured to be open and closed by a gate valve 26. Transfer of the substrate W between the processing chamber 2 and a transfer chamber (not shown) is performed through the transfer port 25.

A stage 3 configured to hold the substrate W substantially horizontally is provided in the processing chamber 2. The stage 3 is formed in a substantially circular shape in a plan view, and is supported by a support 31. The surface of the stage 3 is provided with a substantially circular recess 32 for receiving the substrate W, which has, for example, a diameter of 300 millimeters (mm). The recess 32 has an inner diameter that is slightly greater (e.g., about 1 mm or greater and 4 mm or less) than the diameter of the substrate W. The depth of the recess 32 is, for example, substantially the same as the thickness of the substrate W. Also, the stage 3 is formed of a ceramic material, such as aluminum nitride (AlN) or the like. Alternatively, the stage 3 may be formed of a metal material, such as nickel (Ni) or the like. Rather than the recess 32, a guide ring configured to guide the substrate W may be provided at the circumferential edge of the surface of the stage 3.

For example, a grounded lower electrode 33 is embedded in the stage 3. A temperature adjusting mechanism 34 is embedded below the lower electrode 33. The temperature adjusting mechanism 34 is configured to adjust the substrate W placed on the stage 3 to a set temperature in accordance with a control signal from a controller 9. When the entirety of the stage 3 is formed of a metal, the entirety of the stage 3 functions as a lower electrode. Thus, there is no need to embed the lower electrode 33 in the stage 3. The stage 3 is provided with a plurality of (e.g., three) raising and lowering pins 41 configured to hold and raise/lower the substrate W placed on the stage 3. The material of the raising and lowering pins 41 may be, for example, ceramics, such as alumina (Al₂O₃) or the like, or quartz. The lower ends of the raising and lowering pins 41 are attached to a support plate 42. The support plate 42 is connected to a raising and lowering mechanism 44 provided outside the processing chamber 2 via a raising and lowering shaft 43.

The raising and lowering mechanism 44 is, for example, provided below the gas exhaust chamber 21. A bellows 45 is provided between: an opening 211, for passage of the raising and lowering shaft 43, formed in the bottom surface of the gas exhaust chamber 21; and the raising and lowering mechanism 44. The support plate 42 may have a shape that can be raised and lowered without interfering with the support 31 of the stage 3. The raising and lowering pins 41 are configured to be raised and lowered by the raising and lowering mechanism 44 between an upper side of the surface of the stage 3 and a lower side of the surface of the stage 3. In other words, the raising and lowering pins 41 are configured to project beyond the top surface of the stage 3.

A top wall 27 of the processing chamber 2 is provided with a gas supply 5 via an insulating member 28. The gas supply 5 forms an upper electrode and faces the lower electrode 33. An RF power supply 51 is connected to the gas supply 5 via a matcher 511. The frequency band of the RF power supply 51 is, for example, 450 kHz or higher and 2.45 GHz or lower. Supply of RF power from the RF power supply 51 to the upper electrode (gas supply 5) generates an RF electric field between the upper electrode (gas supply 5) and the lower electrode 33. The gas supply 5 includes a hollow gas diffusion chamber 52. The bottom surface of the gas diffusion chamber 52 is provided with many holes 53 for supplying and dispersing a processing gas in the processing chamber 2. The holes 53 are provided, for example, at equal intervals. A heating mechanism 54 is embedded in the gas supply 5, for example, above the gas diffusion chamber 52. The heating mechanism 54 is heated to a set temperature by supply of power from a power supply (not shown) in accordance with a control signal from the controller 9.

The gas diffusion chamber 52 is provided with a gas supply path 6. The gas supply path 6 communicates with the gas diffusion chamber 52. A gas source 61 is connected upstream the gas supply path 6 via a gas line 62. The gas source 61 includes, for example, supply sources of various processing gases, a mass flow controller, and a valve (which are not shown). The various processing gases are introduced from the gas source 61 into the gas diffusion chamber 52 via the gas line 62.

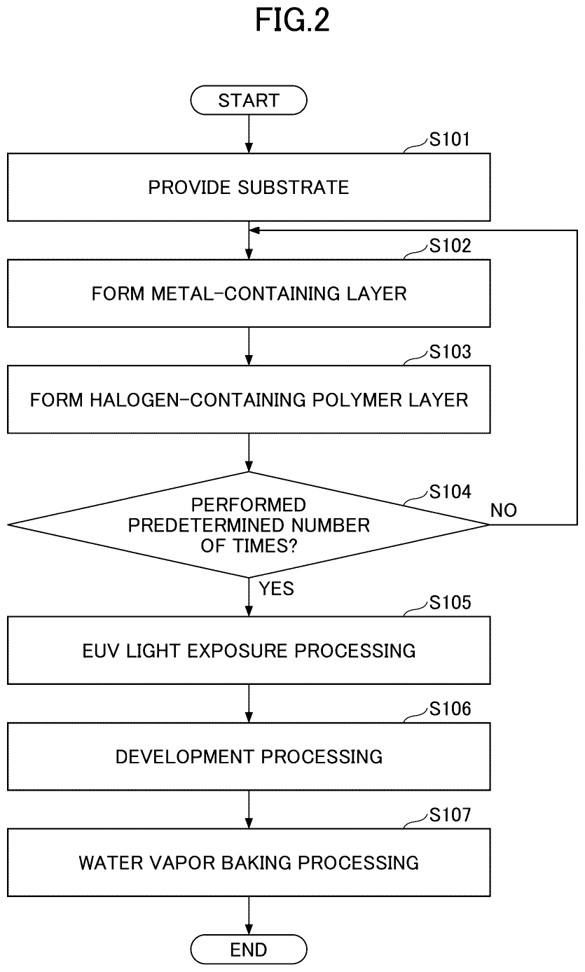

Examples of the various processing gases include a first processing gas containing a metal-containing precursor gas, and a second processing gas containing a halogen-containing precursor gas. The first processing gas is used for forming a metal-containing layer 210 (see FIG. 3A) in step S102 (see FIG. 2), which will be described below. The second processing gas is used for forming a halogen-containing layer 220 (see FIG. 3A) in step S103 (see FIG. 2), which will be described below. Details of the first processing gas and the second processing gas will be described below.

The substrate processing apparatus 1 includes the controller 9. The controller 9 is, for example, a computer, and includes a CPU (Central Processing Unit), a RAM (Random Access Memory), a ROM (Read Only Memory), an auxiliary storage device, and the like. The CPU operates in accordance with a program stored in the ROM or the auxiliary storage device, and controls operation of the substrate processing apparatus 1. The controller 9 may be provided inside the substrate processing apparatus 1 or may be provided outside the substrate processing apparatus 1. When the controller 9 is provided outside the substrate processing apparatus 1, the controller 9 can control the substrate processing apparatus 1 through communication that is wired, wireless, or the like.

Although the substrate processing apparatus 1 has been described taking, as an example, a substrate processing apparatus configured to generate a capacitively coupled plasma (CCP), this is by no means a limitation. The substrate processing apparatus 1 may be a substrate processing apparatus configured to generate a remote plasma by high frequency waves (RF or VHF) or by microwaves (MW). The substrate processing apparatus configured to generate the remote plasma may be a substrate processing apparatus configured to generate a remote plasma in the processing chamber in which the substrate W is housed, or may be a substrate processing apparatus configured to supply the generated remote plasma into the processing chamber in which the substrate W is housed.

### Substrate Processing Method

Next, an example of a substrate processing method will be described with reference to FIG. 2 and FIGS. 3A to 3C. FIG. 2 is a flowchart illustrating an example of a substrate processing method according to the present embodiment. FIGS. 3A to 3C are schematic cross-sectional diagrams of the substrate W including the resist film 230 having a pattern of openings formed by the substrate processing method according to the present embodiment.

In step S101, the substrate W is provided. Here, the substrate W includes a base layer 200 (see FIG. 3A). The controller 9 controls a transfer device (not shown) to transfer the substrate W, including the base layer 200, to the processing chamber 2 of the substrate processing apparatus 1, and to place the substrate W in the recess 32 of the stage 3.

In step S102, the metal-containing layer 210 is formed over the substrate W. Here, the controller 9 controls the gas source 61 to supply the first processing gas from the gas supply 5 into the processing chamber 2 through the holes 53. Also, the controller 9 controls the RF power supply 51 to supply RF power to the upper electrode (gas supply 5). Thus, a plasma of the first processing gas is generated in the processing chamber 2, and the substrate W is exposed to the generated plasma, thereby forming the metal-containing layer 210 over the surface of the substrate W. The metal-containing layer 210 is preferably a metal-containing polymer layer. The metal-containing polymer layer contains metal (M), carbon (C), and hydrogen (H). The metal-containing polymer layer preferably contains abundant C—H bonds. When the metal-containing polymer layer is formed at a low temperature, a film containing abundant hydrogen (H), i.e., a film containing abundant C—H bonds, is formed.

Here, the first processing gas contains the metal-containing precursor gas. The metal-containing precursor gas is a gas containing metal (M) and hydrogen (H). Alternatively, the metal-containing precursor gas is a gas containing metal (M), carbon (C), and hydrogen (H). In other words, the metal-containing precursor gas is represented by chemical formula M_{X}C_{Y}H_{Z}, where M is a metal, each of X and Z is an integer of 1 or greater, and Y is 0 or an integer of 1 or greater. Here, the metal (M) is one selected from Sn, Sb, In, Al, Ti, Mn, Ta, Hf, and W.

Specifically, the metal-containing precursor gas is one selected from Sn(CH₃)₄, SnH(CH₃)₃, SnH₂(CH₃)₂, Sn(C₂H₅)₄, Al(CH₃)₃, Co(C₅H₅)₂, SnR₄, and SnHR₃ (where R is —CH₃, —C₂H₃, —C₃H₅, —C₄H₇, or —C₆H₆).

Also, the first processing gas may contain an additive gas, an inert gas, or both. The additive gas is at least one gas selected from H₂, C₂H₂, and HCl. The inert gas is at least one gas selected from He, Ar, Ne, Xr, and N₂.

An example of a recipe for formation of the metal-containing layer 210 is as follows.
Plasma type: CCP, 13.56 MHz, 10 W or higher and 500 W or lower
Temperature of the stage: 250 degrees Celsius (° C.) or lower
Internal pressure of the processing chamber: 100 mTorr or higher and 20 Torr or lower

In step S103, the halogen-containing layer 220 is formed over the substrate W. Here, the controller 9 controls the gas source 61 to supply the second processing gas from the gas supply 5 into the processing chamber 2 through the holes 53. Also, the controller 9 controls the RF power supply 51 to supply RF power to the upper electrode (gas supply 5). Thus, the plasma of the second processing gas is generated in the processing chamber 2, and the substrate W is exposed to the generated plasma, thereby forming the halogen-containing layer 220 over the surface of the substrate W. The halogen-containing layer 220 is preferably a halogen-containing polymer layer. The halogen-containing polymer layer contains halogen (Ha), carbon (C), and hydrogen (H). The halogen-containing polymer layer preferably contains abundant C—H bonds. When the halogen-containing polymer layer is formed at a low temperature, a film containing abundant hydrogen (H), i.e., a film containing abundant C—H bonds, is formed.

Here, the second processing gas contains a halogen-containing precursor gas. The halogen-containing precursor gas is a gas containing carbon (C) and halogen (Ha). Alternatively, the halogen-containing precursor gas is a gas containing carbon (C), hydrogen (H), and halogen (Ha). In other words, the halogen-containing precursor gas is represented by chemical formula C_{α}H_{β}Ha_{γ}, where Ha is a halogen, each of α and γ is an integer of 1 or greater, and β is 0 or an integer of 1 or greater. The halogen (Ha) is one selected from Cl, F, Br, and I.

Specifically, the halogen-containing precursor gas is one selected from C₂H₂Cl₂, C₂HCl₃, and CCl₄.

Also, the second processing gas may contain an additive gas, an inert gas, or both. The additive gas is at least one gas selected from H₂, C₂H₂, and HCl. The inert gas is at least one gas selected from He, Ar, Ne, Xr, and N₂.

An example of a recipe for formation of the halogen-containing layer 220 is as follows.
Plasma type: CCP, 13.56 MHz, 10 W or higher and 500 W or lower
Temperature of the stage: 250° C. or lower Internal pressure of the processing chamber: 100 mTorr or higher and 20 Torr or lower

In step S104, it is determined whether or not the process of steps S102 and S103 has been performed a predetermined number of times. If the process of steps S102 and S103 has not been performed a predetermined number of times (NO in S104), the process returns to step S102, and the formation of the metal-containing layer 210 (S102) and the formation of the halogen-containing layer 220 (S103) are performed again. If the process of steps S102 and S103 has been performed a predetermined number of times (YES in S104), the process proceeds to step S105. Here, the controller 9 controls a transfer device (not shown) to transfer the substrate W out of the processing chamber 2 of the substrate processing apparatus 1.

The above process forms the resist film 230 having a laminated structure (i.e., a laminate structure) in which the thin-film metal-containing layer 210 and the thin-film halogen-containing layer 220 are alternately laminated is formed over the base layer 200 of the substrate W. The formation of the metal-containing layer 210 over the substrate W (step S102) and the formation of the halogen-containing layer 220 over the substrate W (step S103) are performed in the same processing chamber 2 (see FIG. 1).

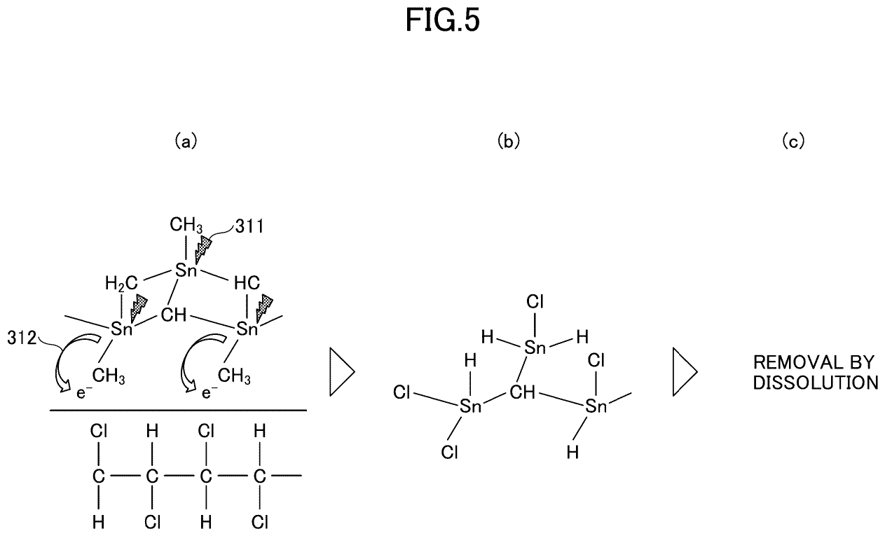

The thickness of the single metal-containing layer 210 is preferably 2 nm or less. The thickness of the single halogen-containing layer 220 is preferably 2 nm or less. Also, the thickness of the resist film 230 having the laminated structure is preferably 20 nm or less and more preferably 15 nm or less. By forming a laminate of the thin films, as described below with reference to FIG. 5, secondary electrons 312 released from metals that absorbed EUV 311 can efficiently reach the halogen-containing layer 220 that is an upper layer of the metal-containing layer 210 and the halogen-containing layer 220 that is a lower layer of the metal-containing layer 210. The halogen and hydrogen dissociated by the secondary electrons 312 can efficiently reach the metal-containing layer 210 that is an upper layer of the halogen-containing layer 220 and the metal-containing layer 210 that is a lower layer of the halogen-containing layer 220.

In the flowchart of the substrate processing method illustrated in FIG. 2, the metal-containing layer 210 is formed first, the halogen-containing layer 220 is formed next, and subsequently the process is repeatedly performed. This is by no means a limitation. The halogen-containing layer 220 may be formed first, the metal-containing layer 210 may be formed next, and subsequently the process may be repeatedly performed.

In the example illustrated in FIG. 3A, the bottom layer (the layer in contact with the base layer 200) of the resist film 230 is the metal-containing layer 210. That is, the metal-containing layer 210 is formed over the base layer 200, and the halogen-containing layer 220 is formed over the metal-containing layer 210. The structure of the resist film 230 is not limited to this. The bottom layer of the resist film 230 may be the halogen-containing layer 220. That is, the halogen-containing layer 220 may be formed over the base layer 200, and the metal-containing layer 210 may be formed over the halogen-containing layer 220. Also, in FIG. 3A, the top layer of the resist film 230 is the metal-containing layer 210. However, this is by no means a limitation. The top layer of the resist film 230 may be the halogen-containing layer 220.

In step S105, extreme ultraviolet (EUV) light exposure processing is performed on the substrate W including the resist film 230 having the laminated structure formed over the base layer 200. Here, the resist film 230 of the substrate W is irradiated with EUV light through a photomask having a predetermined pattern in a nitrogen atmosphere, thereby forming, in the resist film 230, an exposed portion 310 (see FIG. 3B) irradiated with the EUV light and unexposed portions 320 (see FIG. 3B) not irradiated with the EUV light.

In step S106, development processing is performed on the substrate W that has undergone the EUV light exposure processing. Here, the development processing selectively removes the exposed portion 310 (see FIG. 3C) of the resist film 230. The development processing can use at least one of a wet process or a dry process.

When the development processing is a wet process, the substrate W is exposed to an organic solvent to selectively remove the exposed portion 310 of the resist film 230. The organic solvent for use can be alcohol or the like.

When the development processing is a dry process, the substrate W is exposed to a halogen-containing gas to selectively remove the exposed portion 310 (see FIG. 3C) of the resist film 230. The halogen-containing gas for use can be at least one of HBr or HCl.

In step S107, water vapor baking processing is performed on the substrate W that has undergone the development processing. Here, the substrate W that has undergone the development processing is thermally processed (baked) in a water vapor atmosphere. The thermal processing in the water vapor atmosphere oxidizes the resist film 230 of the unexposed portions 320.

After the thermal processing in the water vapor atmosphere, additional thermal processing may be performed in a nitrogen atmosphere.

As such, according to the substrate processing method illustrated in FIG. 2, it is possible to form the resist film 230 over the base layer 200.

Here, the resist film 230 formed by the substrate processing apparatus 1 can be a positive-type resist film in which the exposed portion 310 can be selectively removed. For example, when a contact hole or the like is formed in the base layer 200, it is suitable to use a positive-type resist film compared to a negative-type resist film.

Also, the resist film 230 formed by the substrate processing apparatus 1 can be formed through chemical vapor deposition using a plasma. Thus, the film thickness of the resulting resist film can be reduced compared to a resist film formed by coating a polymer.

Also, by reducing the film thickness of the resist film 230, when forming a pattern in the base layer 200 using, as a mask, the resist film 230 having a pattern of openings, it is possible to suppress pattern collapse in the base layer 200.

### Processing of Resist Film

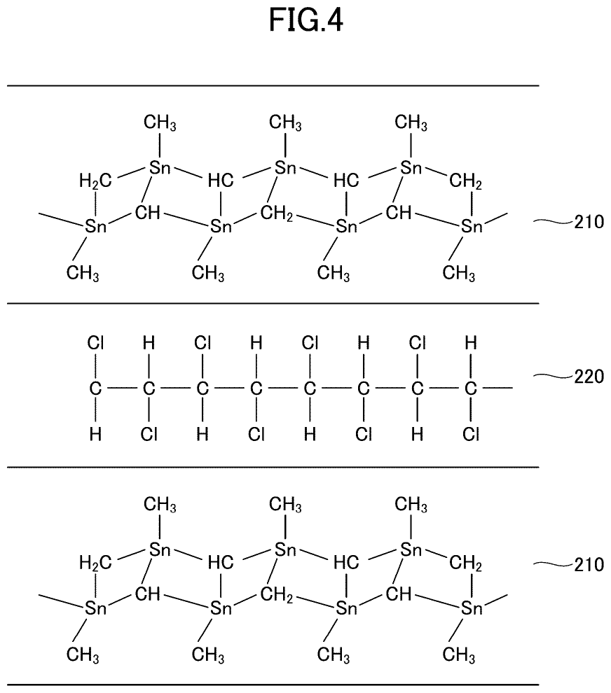

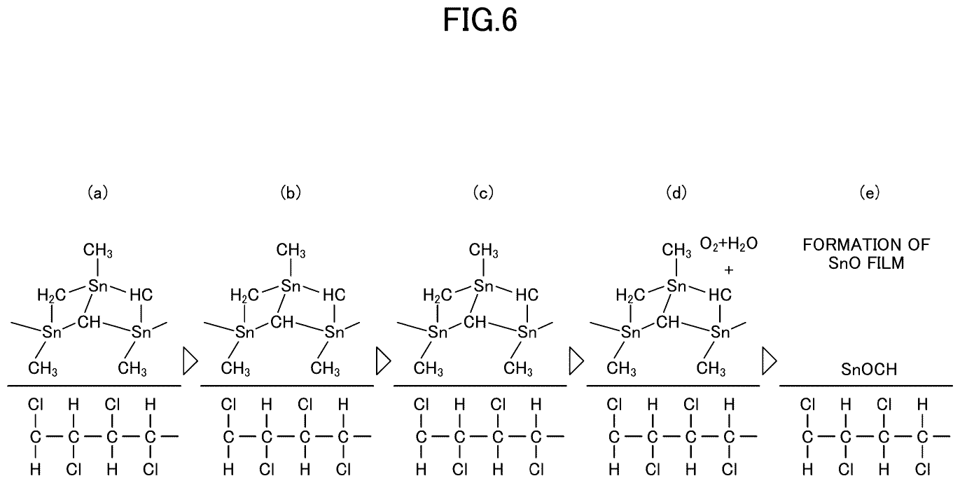

Next, processing of the resist film 230 formed by the substrate processing apparatus 1 will be further described with reference to FIGS. 4 to 6. FIG. 4 is a diagram schematically illustrating the structure of the resist film 230 having the laminated structure formed by the substrate processing apparatus 1 according to the present embodiment. FIG. 5 is a diagram schematically illustrating the structure, in each step, of the resist film 230 of the exposed portion 310. FIG. 6 is a diagram schematically illustrating the structure, in each step, of the resist film 230 of the unexposed portions 320.

Also, in FIGS. 4 to 6 and the following description, a case in which tetramethyltin (Sn(CH₃)₄) is used as the metal-containing precursor gas and chloroethylene (C₂H₂Cl₂) is used as the halogen-containing precursor gas will be taken as an example.

As illustrated in FIG. 4, the metal-containing layer 210 is formed by bonding Sn(CH₃)₄ in the processing of step S102. Also, the halogen-containing layer 220 is formed by bonding C₂H₂Cl₂ in the processing of step S103. Then, by repeatedly performing the processing of step S102 and the processing of step S103, the metal-containing layer 210 and the halogen-containing layer 220 are alternately laminated to form the resist film 230 (see FIG. 3A).

Next, in step S105, exposure processing is performed on the substrate W. Here, the resist film 230 of the substrate W is irradiated with EUV light having a wavelength of 13 nm and high-energy photons of 95 eV through a photomask having a predetermined pattern, thereby performing the exposure processing.

(a) and (b) of FIG. 5 are diagrams schematically illustrating the structure of the resist film 230 of the exposed portion 310 in the exposure processing. As illustrated in (a) of FIG. 5, the EUV 311, with which the substrate W has been irradiated, is absorbed by the metal atoms (Sn) of the metal-containing layer 210, and the secondary electrons 312 are released from the metal atoms (Sn).

The released secondary electrons 312 activate Sn—C bonds between the metal atoms (Sn) and carbon (C) around the metal atoms (Sn). Also, the released secondary electrons 312 reach the upper and lower halogen-containing layers 220 from the metal-containing layer 210, and activate C—Cl bonds and C—H bonds in the halogen-containing layer 220 to release halogen (Cl) and hydrogen (H). The halogen-containing layer 220 is preferably a halogen-containing polymer layer containing abundant C—H bonds. The halogen-containing layer 220 containing abundant hydrogen (H) is easily decomposed by the EUV light and the secondary electrons to release halogen (Cl) and hydrogen (H).

When the halogen (Cl) and the hydrogen (H) released from the halogen-containing layer 220 are bonded to the activated metal atoms (Sn) of the metal-containing layer 210, a portion of the stable Sn—C bonds is modified to SnH_{N}Cl_{M} (where at least one of N or M is an integer of 1 or greater) as illustrated in (b) of FIG. 5, resulting in changing to an unstable structure that is to be released in subsequent development processing. The metal-containing layer 210 is preferably a metal-containing polymer layer containing abundant C—H bonds. When the metal-containing polymer layer containing abundant C—H bonds is bonded to the halogen (Cl) and the hydrogen (H) released from the halogen-containing layer 220, solubility in the development processing is improved.

(a) and (b) of FIG. 6 are diagrams schematically illustrating the structure of the resist film 230 of the unexposed portions 320 in the exposure processing. As illustrated in (a) and (b) of FIG. 6, stable and strong bonds are maintained in the metal-containing layer 210 and the halogen-containing layer 220 of the unexposed portion 320 as in the state illustrated in FIG. 4.

Next, in step S106, development processing is performed on the substrate W.

(c) of FIG. 5 is a diagram schematically illustrating the structure of the resist film 230 of the exposed portion 310 in the development processing. The exposed portion 310 changes to an unstable structure in the exposure processing as illustrated in (b) of FIG. 5, and thus the resist film 230 of the exposed portion 310 is dissolved and removed as illustrated in (c) of FIG. 5.

(c) of FIG. 6 is a diagram schematically illustrating the structure of the resist film 230 of the unexposed portion 320 in the development processing. The unexposed portion 320 is maintained to have stable and strong bonds even after the exposure processing as illustrated in (b) of FIG. 6, and thus the resist film 230 of the unexposed portion 320 is left without being removed by the development processing as illustrated in (c) of FIG. 6.

Next, in step S107, an oxidation annealing step (water vapor baking processing) is performed on the substrate W. (d) of FIG. 6 is a diagram schematically illustrating the structure of the resist film 230 of the unexposed portion 320 in the oxidation annealing step. Here, annealing is performed on the substrate W by supply of an oxidizing agent (O₂, H₂O, or both). As a result, the thin-film metal-containing layer 210 containing the metal atoms Sn is changed to an oxide film of a stable metal oxide (SnO). That is, the metal-containing layer 210 turns into an SnOCH film. The metal oxide film has excellent etching resistance in dry etching. Therefore, it is possible to successfully dry-etch the base layer 200 using, as a mask, the resist film 230 changed to the metal oxide film. In other words, the resist film 230 functions as a hard mask. Thus, formation of a hard mask between the resist film and the base layer 200 to be processed can be omitted, and cost of substrate processing can be reduced.

The above description has been made based on an example in which the resist film 230, including the metal-containing layer 210 and the halogen-containing layer 220 alternately laminated, is formed through plasma CVD. This is by no means a limitation. Thermal CVD may be used to form the resist film 230 including the metal-containing layer 210 and the halogen-containing layer 220 alternately laminated. Also, a remote plasma may be used to form the resist film 230 including the metal-containing layer 210 and the halogen-containing layer 220 alternately laminated. Alternatively, the metal-containing layer 210 and the halogen-containing layer 220 may be formed by different film forming methods. The metal-containing layer 210 may be formed through physical vapor deposition (PVD).

The metal-containing precursor gas may be a gas containing halogen (Ha) in addition to metal (M), carbon (C), and hydrogen (H). That is, the metal-containing precursor gas is represented by chemical formula M_{W}Ha_{X}C_{Y}H_{Z}, where M is a metal, Ha is a halogen, W is an integer of 1 or greater, and each of X, Y, and Z is 0 or an integer of 1 or greater. Specifically, the metal-containing precursor gas is one selected from SnH₄, SnH₃Cl, SnCl₃C₄H₉, AlCl₃, Al(C₂H₅)₂Cl, TiCl₄, TaCl₅, GeH₄, and Ge(CH₃)₄.

The metal-containing precursor gas may be a gas containing nitrogen (N), oxygen (O), or both in addition to metal (M), carbon (C), and hydrogen (H). That is, the metal-containing precursor gas is represented by chemical formula M_{V}N_{W}H_{X}C_{Y}O_{Z}, where M is a metal, V is an integer of 1 or greater, and each of W, X, Y, and Z is 0 or an integer of 1 or greater. Specifically, the metal-containing precursor gas is one selected from Sn(N(CH₃)₂)₄, Sn(O—C₄H₉)₄, Al(N(CH₃)₂)₃, Ti(N(CH₃)₂)₄, Ta(N(CH₃)₂)₅, Hf(N(CH₃)₂)₄, and Al(CH₃)₂OC₃H₇.

The metal-containing precursor gas may be a combination of these gases.

The second processing gas may be a gas mixture of a halogen-containing precursor gas represented by chemical formula C_{α}H_{β}Ha_{γ} and an additive gas represented by chemical formula C_{X}H_{Y}. In these chemical formulae, Ha is a halogen, each of α and γ is an integer of 1 or greater, and β is 0 or an integer of 1 or greater. The halogen (Ha) is one selected from Cl, F, Br, and I. Also, each of X and Y is an integer of 1 or greater. For example, the additive gas is C₂H₂, and the second processing gas may be a gas mixture of C₂H₂Cl₂ and C₂H₂. By adding the additive gas to the second processing gas, it is possible to form a stable halogen-containing layer.

Also, the second processing gas may be a gas mixture of a halogen-containing precursor gas represented by chemical formula C_{α}H_{β}Ha_{γ} and an additive gas represented by chemical formulae C_{X}H_{Y} and Ha_{M}H_{N}. In these chemical formulae, Ha is a halogen, each of α and γ is an integer of 1 or greater, and β is 0 or an integer of 1 or greater. The halogen (Ha) is one selected from Cl, F, Br, and I. Also, each of X and Y is an integer of 1 or greater. M is an integer of 1 or greater, and N is 0 or an integer of 1 or greater. For example, the additive gas is a gas mixture of C₂H₂ and one selected from Cl₂ and HCl. The second processing gas may be a gas mixture of C₂H₂Cl₂, C₂H₂, and Cl₂, or may be a gas mixture of C₂H₂Cl₂, C₂H₂, and HCl. By adding the additive gas to the second processing gas, it is possible to form a stable halogen-containing layer.

The resist film 230 may have a structure in which the metal-containing layer 210, the halogen-containing layer 220, and an organic film (hydrocarbon layer) are laminated. That is, the formation of the laminated structure film (resist film) may further include forming a hydrocarbon layer (not shown) over the substrate W in addition to the formation of the metal-containing layer 210 over the substrate W (see step S102) and the formation of the halogen-containing layer 220 over the substrate W (see step S103), and these layer forming steps may be repeatedly performed to form the laminated structure film (resist film) over the substrate W. Also, the formation of the hydrocarbon layer (not shown) over the substrate W is preferably performed after the formation of the metal-containing layer 210 over the substrate W (see step S102) yet before the formation of the halogen-containing layer 220 over the substrate W (see step S103). By forming the hydrocarbon layer between the metal-containing layer 210 and the halogen-containing layer 220, it is possible to suppress reaction between the metal of the metal-containing layer 210 and the halogen of the halogen-containing layer 220. The top layer of the resist film 230 may be a thick film layer of the halogen-containing layer 220 or the organic film (hydrocarbon layer). This can prevent native oxidation of the metal-containing layer 210 before the exposure processing and the development processing.

The present disclosure can provide, in one aspect, a substrate processing method for forming a resist film that is a thin film and in which an exposed portion can be selectively removed.

Although the substrate processing apparatus 1 according to the present embodiment and the substrate processing method according to the present embodiment have been described above, the present disclosure is not limited to the above-described embodiments, and various modifications and improvements are possible within the scope of the present disclosure described in claims recited.

### CLAUSES

### Clause 1

A substrate processing method, including:
forming a laminated structure film over a substrate, the laminated structure film including a metal-containing layer and a halogen-containing layer that are laminated;
irradiating the laminated structure film with extreme ultraviolet light in a predetermined pattern to form, in the laminated structure film, an exposed portion irradiated with the extreme ultraviolet light and an unexposed portion not irradiated with the extreme ultraviolet light; and
selectively removing the exposed portion of the laminated structure film.

### Clause 2

The substrate processing method according to clause 1, wherein
the metal-containing layer is formed by generating a plasma by supply of a first processing gas containing a metal-containing precursor gas, and exposing the substrate to the generated plasma.

### Clause 3

The substrate processing method according to clause 2, wherein
the metal-containing precursor gas is represented by chemical formula M_{X}C_{Y}H_{Z}, where M is a metal, each of X and Z is an integer of 1 or greater, and Y is 0 or an integer of 1 or greater.

### Clause 4

The substrate processing method according to clause 2, wherein
the metal-containing precursor gas is represented by chemical formula M_{W}Ha_{X}C_{Y}H_{Z}, where M is a metal, Ha is a halogen, W is an integer of 1 or greater, and each of X, Y, and Z is 0 or an integer of 1 or greater.

### Clause 5

The substrate processing method according to clause 2, wherein
the metal-containing precursor gas is represented by chemical formula M_{V}N_{W}H_{X}C_{Y}O_{Z}, where M is a metal, V is an integer of 1 or greater, and each of W, X, Y, and Z is 0 or an integer of 1 or greater.

### Clause 6

The substrate processing method according to clause 3, wherein
the metal (M) is one selected from Sn, Sb, In, Al, Ti, Mn, Ta, Hf, and W.

### Clause 7

The substrate processing method according to clause 2, wherein
the metal-containing precursor gas is one selected from Sn(CH₃)₄, SnH(CH₃)₃, SnH₂(CH₃)₂, Sn(C₂H₅)₄, Al(CH₃)₃, Co(C₅H₅)₂, SnR₄, SnHR₃, (where R is —CH₃, —C₂H₃, —C₃H₅, —C₄H₇, or —C₆H₆), SnH₄, SnH₃Cl, SnCl₃C₄H₉, AlCl₃, Al(C₂H₅)₂Cl, TiCl₄, TaCl₅, GeH₄, Ge(CH₃)₄, Sn(N(CH₃)₂)₄, Sn(O—C₄H₉)₄, Al(N(CH₃)₂)₃, Ti(N(CH₃)₂)₄, Ta(N(CH₃)₂)₅, Hf(N(CH₃)₂)₄, and Al(CH₃)₂OC₃H₇.

### Clause 8

The substrate processing method according to clause 1, wherein
the halogen-containing layer is formed by generating a plasma by supply of a second processing gas containing a halogen-containing precursor gas, and exposing the substrate to the generated plasma.

### Clause 9

The substrate processing method according to clause 8, wherein
the halogen-containing precursor gas is represented by chemical formula C_{α}H_{β}Ha_{γ}, where Ha is a halogen, each of α and γ is an integer of 1 or greater, and β is 0 or an integer of 1 or greater.

### Clause 10

The substrate processing method according to clause 9, wherein
the halogen (Ha) is one selected from Cl, F, Br, and I.

### Clause 11

The substrate processing method according to clause 8, wherein
the halogen-containing precursor gas is one selected from C₂H₂Cl₂, C₂HCl₃, and CCl₄.

### Clause 12

The substrate processing method according to clause 8, wherein
the second processing gas further contains an additive gas.

### Clause 13

The substrate processing method according to clause 12, wherein
the additive gas is represented by chemical formula C_{X}H_{Y}, where each of X and Y is an integer of 1 or greater.

### Clause 14

The substrate processing method according to clause 12, wherein
the additive gas is represented by the chemical formula C_{X}H_{Y} and chemical formula Ha_{M}H_{N}, where Ha is a halogen, each of X, Y, and M is an integer of 1 or greater, and N is 0 or an integer of 1 or greater, and
the halogen (Ha) is one selected from Cl, F, Br, and I.

### Clause 15

The substrate processing method according to clause 12, wherein
the additive gas is C₂H₂.

### Clause 16

The substrate processing method according to clause 12, wherein
the additive gas is a gas mixture of C₂H₂ and Cl₂ or a gas mixture of C₂H₂ and HCl.

### Clause 17

The substrate processing method according to clause 1, wherein
the formation of the laminated structure film includes forming the metal-containing layer over the substrate and forming the halogen-containing layer over the metal-containing layer.

### Clause 18

The substrate processing method according to clause 1, wherein
the formation of the laminated structure film includes forming the halogen-containing layer over the substrate and forming the metal-containing layer over the halogen-containing layer.

### Clause 19

The substrate processing method according to clause 1, wherein
the formation of the laminated structure film includes repeatedly performing formation of the metal-containing layer and formation of the halogen-containing layer a plurality of times.

### Clause 20

The substrate processing method according to clause 19, wherein
the formation of the metal-containing layer and the formation of the halogen-containing layer are performed in a same processing chamber.

### Clause 21

The substrate processing method according to clause 1, wherein
the formation of the laminated structure film further includes forming a hydrocarbon layer.

### Clause 22

The substrate processing method according to clause 21, wherein
the formation of the hydrocarbon layer is performed after formation of the metal-containing layer yet before formation of the halogen-containing layer.

### Clause 23

The substrate processing method according to clause 21, wherein
the formation of the laminated structure film includes forming, as a top layer, the halogen-containing layer or the hydrocarbon layer.

### Clause 24

The substrate processing method according to clause 1, wherein
formation of the metal-containing layer and formation of the halogen-containing layer are performed at a temperature of 250° C. or lower.

### Clause 25

The substrate processing method according to clause 1, wherein
a thickness of the metal-containing layer is 2 nm or less as a single layer, and
a thickness of the halogen-containing layer is 2 nm or less as a single layer.

### Clause 26

The substrate processing method according to clause 1, wherein
a thickness of the laminated structure film is 15 nm or less.

### Clause 27

The substrate processing method according to clause 1, wherein
the irradiation of the laminated structure film with the extreme ultraviolet light is performed in a nitrogen atmosphere.

### Clause 28

The substrate processing method according to clause 1, wherein
the selective removal of the exposed portion is a wet process in which the substrate is exposed to an organic solvent to selectively remove the exposed portion.

### Clause 29

The substrate processing method according to clause 1, wherein
the selective removal of the exposed portion is a dry process in which the substrate is exposed to a halogen-containing gas to selectively remove the exposed portion.

### Clause 30

The substrate processing method according to clause 1, further including:
after the selective removal of the exposed portion, thermally processing the substrate.

### Clause 31

The substrate processing method according to clause 30, wherein
the thermal processing of the substrate is performed in a water vapor atmosphere.

### Clause 32

The substrate processing method according to clause 31, further including:
after the thermal processing in the water vapor atmosphere, thermally processing the substrate in a nitrogen atmosphere.

What is claimed is:

1. A substrate processing method, comprising:
forming a laminated structure film over a substrate, the laminated structure film including a metal-containing layer and a halogen-containing layer that are laminated;
irradiating the laminated structure film with extreme ultraviolet light in a predetermined pattern to form, in the laminated structure film, an exposed portion irradiated with the extreme ultraviolet light and an unexposed portion not irradiated with the extreme ultraviolet light; and
selectively removing the exposed portion of the laminated structure film.

2. The substrate processing method according to claim 1, wherein
the metal-containing layer is formed by generating a plasma by supply of a first processing gas containing a metal-containing precursor gas, and exposing the substrate to the generated plasma.

3. The substrate processing method according to claim 2, wherein
the metal-containing precursor gas is represented by chemical formula M_{X}C_{Y}H_{Z}, where M is a metal, each of X and Z is an integer of 1 or greater, and Y is 0 or an integer of 1 or greater.

4. The substrate processing method according to claim 2, wherein
the metal-containing precursor gas is represented by chemical formula M_{W}Ha_{X}C_{Y}H_{Z}, where M is a metal, Ha is a halogen, W is an integer of 1 or greater, and each of X, Y, and Z is 0 or an integer of 1 or greater.

5. The substrate processing method according to claim 2, wherein
the metal-containing precursor gas is represented by chemical formula M_{V}N_{W}H_{X}C_{Y}O_{Z}, where M is a metal, V is an integer of 1 or greater, and each of W, X, Y, and Z is 0 or an integer of 1 or greater.

6. The substrate processing method according to claim 3, wherein
the metal (M) is one selected from Sn, Sb, In, Al, Ti, Mn, Ta, Hf, and W.

7. The substrate processing method according to claim 2, wherein
the metal-containing precursor gas is one selected from Sn(CH₃)₄, SnH(CH₃)₃, SnH₂(CH₃)₂, Sn(C₂H₅)₄, Al(CH₃)₃, Co(C₅H₅)₂, SnR₄, SnHR₃, (where R is —CH₃, —C₂H₃, —C₃H₅, —C₄H₇, or —C₆H₆), SnH₄, SnH₃Cl, SnCl₃C₄H₉, AlCl₃, Al(C₂H₅)₂Cl, TiCl₄, TaCl₅, GeH₄, Ge(CH₃)₄, Sn(N(CH₃)₂)₄, Sn(O—C₄H₉)₄, Al(N(CH₃)₂)₃, Ti(N(CH₃)₂)₄, Ta(N(CH₃)₂)₅, Hf(N(CH₃)₂)₄, and Al(CH₃)₂OC₃H₇.

8. The substrate processing method according to claim 1, wherein
the halogen-containing layer is formed by generating a plasma by supply of a second processing gas containing a halogen-containing precursor gas, and exposing the substrate to the generated plasma.

9. The substrate processing method according to claim 8, wherein
the halogen-containing precursor gas is represented by chemical formula C_{α}H_{β}Ha_{γ}, where Ha is a halogen, each of α and γ is an integer of 1 or greater, and β is 0 or an integer of 1 or greater.

10. The substrate processing method according to claim 9, wherein
the halogen (Ha) is one selected from Cl, F, Br, and I.

11. The substrate processing method according to claim 8, wherein
the halogen-containing precursor gas is one selected from C₂H₂Cl₂, C₂HCl₃, and CCl₄.

12. The substrate processing method according to claim 8, wherein
the second processing gas further contains an additive gas.

13. The substrate processing method according to claim 12, wherein
the additive gas is represented by chemical formula C_{X}H_{Y}, where each of X and Y is an integer of 1 or greater.

14. The substrate processing method according to claim 12, wherein
the additive gas is represented by the chemical formula C_{X}H_{Y} and chemical formula Ha_{M}H_{N}, where Ha is a halogen, each of X, Y, and M is an integer of 1 or greater, and N is 0 or an integer of 1 or greater, and
the halogen (Ha) is one selected from Cl, F, Br, and I.

15. The substrate processing method according to claim 12, wherein
the additive gas is C₂H₂.

16. The substrate processing method according to claim 12, wherein
the additive gas is a gas mixture of C₂H₂ and Cl₂ or a gas mixture of C₂H₂ and HCl.

17. The substrate processing method according to claim 1, wherein
the formation of the laminated structure film includes forming the metal-containing layer over the substrate and forming the halogen-containing layer over the metal-containing layer.

18. The substrate processing method according to claim 1, wherein
the formation of the laminated structure film includes forming the halogen-containing layer over the substrate and forming the metal-containing layer over the halogen-containing layer.

19. The substrate processing method according to claim 1, wherein
the formation of the laminated structure film includes repeatedly performing formation of the metal-containing layer and formation of the halogen-containing layer a plurality of times.

20. The substrate processing method according to claim 19, wherein
the formation of the metal-containing layer and the formation of the halogen-containing layer are performed in a same processing chamber.
